(19) United States
(12) Patent Application Publication
(10) Pub. No.: US 2025/0259924 A1
(43) Pub. Date: Aug. 14, 2025

(54) TRANSFORMER-BASED INTEGRATED CIRCUIT PACKAGES HAVING FRACTIONAL COIL STRUCTURES

(71) Applicant: Allegro MicroSystems, LLC, Manchester, NH (US)

(72) Inventors: Paul A. David, Bow, NH (US); Vijay Mangtani, Nashua, NH (US); William P. Taylor, Amherst, NH (US)

(73) Assignee: Allegro MicroSystems, LLC, Manchester, NH (US)

(21) Appl. No.: 18/438,831

(22) Filed: Feb. 12, 2024

(51) Int. Cl. H01L 23/522; H01F 1/06; H01F 1/10; H01F 1/34; H01F 27/28; H01F 41/02; H01L 23/00; H01L 23/495; H01L 25/065; H05K 1/18

(52) U.S. Cl. CPC H01L 23/5227; H01F 1/06; H01F 1/10; H01F 1/34; H01F 27/28; H01F 41/02; H01L 23/49575; H05K 1/181; H01L 24/16; H01L 25/0655; H01L 2224/16225; H01L 2924/181

(57) ABSTRACT

Systems, structures, packages, circuits, and methods provide transformers having fractional coil structures. A first plurality of conductive traces in a substrate forms first portions of first and second transformer coils. Two or more fractional coil structures are provided, with each including a second plurality of conductive traces forming second portions of the transformer coils and configured to extend around a portion of a provided magnetic core. The fractional coil structures are configured such that first (primary) and second (secondary) transformer coils are formed when the second plurality of conductive traces is brought into contact with the first plurality of conductive traces. A transformer having one or more fractional coil structures can be included in integrated circuit (chip) packages or modules. The packages and modules may include various types of circuits; in some examples, chip packages or modules may include a galvanically isolated gate driver or other high voltage circuit.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Such galvanic isolation can be used to separate circuits in order to protect users from coming into direct contact with hazardous voltages.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits.

Transformers used for magnetic-coupling isolation barriers typically utilize a magnetic core to provide a magnetic path to channel flux created by the currents flowing in the primary and secondary sides of the transformer. Magnetic-coupling isolation barriers have been shown to have various drawbacks, including manufacturing problems, for integrated circuit (IC) packages due to the included magnetic core.

### SUMMARY

Aspects of the present disclosure are directed to transformer-based circuits, circuit portions, and packages, including integrated circuit (IC) packages, having one or more fractional coil structures, and related manufacturing methods.

One general aspect of the present disclosure includes a transformer-based integrated circuit (IC) package. The transformer-based integrated circuit package can include: a substrate having a first plurality of conductive traces; a core disposed on the substrate, where the core includes a soft ferromagnetic material; and a pair of fractional coil structures, each having a second plurality of conductive traces and configured to extend around a portion of the core, where the pair of fractional coil structures is configured such that primary and secondary coils are formed when the second plurality of conductive traces is brought into contact with the first plurality of conductive traces; where the primary and secondary coils are configured with the core as a transformer. Other embodiments of this aspect include corresponding computer systems, apparatus, and computer programs recorded on one or more computer storage devices, each configured to perform the actions of the methods.

Implementations may include one or more of the following features. The IC package may include at least one semiconductor die disposed on the substrate. The at least one semiconductor die may include an integrated circuit (IC). The IC can be connected to the secondary coil. The transformer can be configured as a step-up transformer, a step-down transformer, or a power transformer. The IC may include a gate driver. The substrate may include a printed circuit board (PCB). The PCB may include suitable PCB material(s), e.g., FR4, FR5, etc. The core may include ferrite. The core may include iron powder. The core may include a laminated metal core or a laminated non-metal core, e.g., laminated ferrite. At least one fractional coil structure may include a semiconductor die disposed on a substrate, where the semiconductor die includes an integrated circuit (IC). The IC may be connected to a subset of the second plurality of conductive traces. The IC may include a gate driver, and where the second plurality of conductive traces is connected to the second (secondary) coil. At least one fractional coil structure may include a leadframe. The core may include a plurality of core portions. The plurality of core portions are connected at joints including ferrite-loaded epoxy. The IC package may include a package body including the substrate. The package body may include a molding material. The package body may include a potting material.

Another general aspect of the present disclosure includes a method of making a transformer-based integrated circuit (IC) package. The method can include: providing a substrate having a first plurality of conductive traces; providing a core disposed on the substrate, where the core includes a soft ferromagnetic material; and providing a pair of fractional coil structures, each having a second plurality of conductive traces and configured to extend around a portion of the core, where the pair of fractional coil structure is configured such that primary and secondary coils are formed when the second plurality of conductive traces is brought into contact with the first plurality of conductive traces; where the primary and secondary coils are configured with the core as a transformer.

Implementations may include one or more of the following features. The method may include providing at least one semiconductor die disposed on the substrate, where the at least one semiconductor die may include an integrated circuit (IC). The IC can be connected to the secondary coil. The transformer can be configured as a step-up transformer, a step-down transformer, or a power transformer. The IC may include a gate driver. The substrate may include a printed circuit board (PCB). The PCB may include suitable PCB material(s), e.g., FR4, FR5, etc. The core may include ferrite. The core may include iron powder. The core may include a laminated metal core or a laminated non-metal core, e.g., ferrite. At least one (e.g., of the pair) of fractional coil structures may include an IC die disposed on a substrate, where the IC die may include an IC. The IC can be connected to a subset of the second plurality of conductive traces. The IC may include a gate driver, and where the second plurality of conductive traces is connected to the secondary coil. At least one fractional coil structures may include a leadframe.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIG. 1 is a diagram showing structure of an example transformer-based integrated circuit (IC) package having fractional coil structures at successive stages of fabrication, in accordance with the present disclosure;

FIG. 2 is a diagram showing an example method of fabricating a transformer-based integrated circuit (IC) package having fractional coil structures with steps corresponding to the structures shown in FIG. 1;

FIG. 3 is a diagram showing Views A-B of an example transformer-based integrated circuit (IC) package structure having fractional coil structures in an unassembled state and an assembled state, respectively, in accordance with the present disclosure;

FIG. 4A is a diagram of an example of structure for a contactor molding and leadforming process, in accordance with the present disclosure;

FIG. 4B is a diagram of an example long-lead dual in-line-package (DIP), in accordance with the present disclosure;

FIG. 5 is a diagram with views showing different lead configurations, in accordance with example embodiments of the present disclosure;

FIG. 6 is a diagram showing structure of a further example transformer-based integrated circuit (IC) package having fractional coil structures at successive stages of fabrication, in accordance with the present disclosure;

FIG. 7 is a diagram showing an example method of fabricating a transformer-based integrated circuit (IC) package having fractional coil structures with steps corresponding to the structures shown in FIG. 6;

FIG. 8 is a diagram showing Views A-D of an example transformer-based integrated circuit (IC) package having fractional coil structures with included ICs, in accordance with the present disclosure; and

FIG. 9 is a diagram showing an example method of fabricating a transformer-based integrated circuit (IC) package having fractional coil structures, in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, structures, circuits, and methods providing transformers and transformer structures that can be used for galvanic isolation (a.k.a., voltage isolation). Embodiments and examples can include fractional (fractional) coil structures used with a core in a transformer configuration. In some embodiments, a transformer with fractional coil structures may have, e.g., a step up, a step down, or a power transformer configuration. Some embodiments and examples can include integrated circuit (IC) packages or modules with transformer having fractional coil structures. Some embodiments can include transformer packages having fractional coil structures, not necessarily including one or more ICs; other passive and/or active components may be included in such transformer packages.

The IC packages and modules may include various types of circuits; in some examples, IC packages or modules may include a galvanically isolated gate driver or other high voltage circuit, etc. First and second semiconductor die having one or more integrated circuits (a.k.a., “IC die”) can be included in the packages. Such integrated circuits can include, e.g., but are not limited to, high-voltage circuits such as galvanically-isolated gate drivers configured to drive an external gate on a solid-state switch, e.g., a field effect transistor (FET), a metal oxide semiconductor FET (MOSFET), a metal semiconductor FET (MESFET), a gallium nitride FET (GaN FET), a high electron mobility transistor (HEMT), a silicon carbide FET (SIC FET), an insulated gate bipolar transistor (IGBT), or another load.

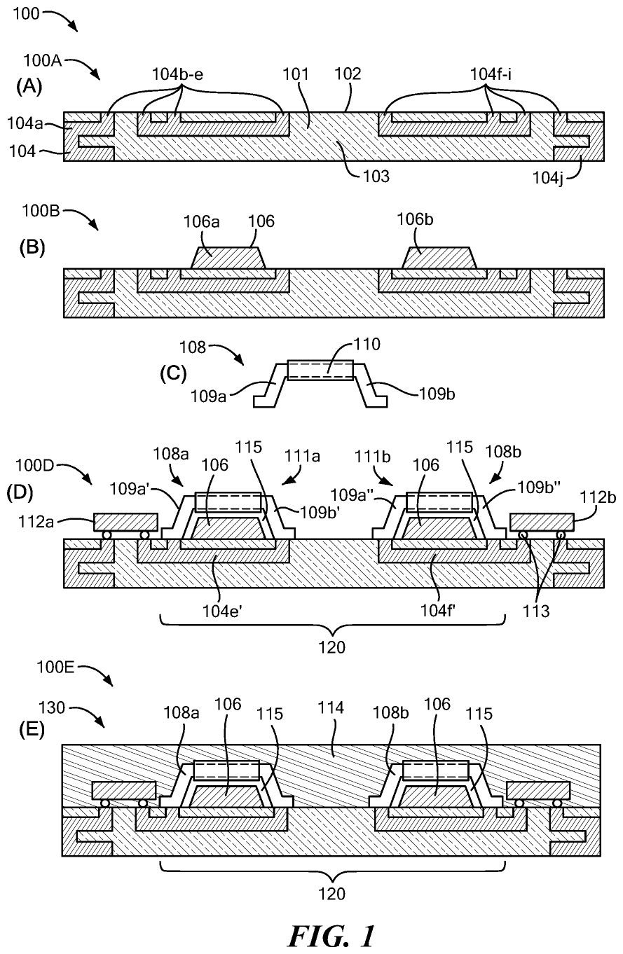

FIG. 1 is a diagram showing structure of an example transformer-based integrated circuit (IC) package 100 having fractional coil structures at successive stages of fabrication (shown in Views A-E), in accordance with the present disclosure.

As shown in View A, structure 100A includes substrate 101 including opposed first and second sides (surfaces) 102, 103 and a plurality of conductive traces/conductive structures 104, which can be (reside) on a surface of or within substrate 101. In some embodiments, substrate 101 may include or be formed from a molded lead frame, and conductive traces/structures 104 may include, but are not limited to, conductive lead frame regions, e.g., in an epoxy mold compound or other molded plastic body. As explained in further detail below, the plurality of conductive traces/structures 104 can include first and second groups (pluralities, sub-groups, subsets, or sub-pluralities) that are galvanically separated for use with an associated transformer. In the example shown, conductive traces 104 include conductive traces 104a-104j. Some conductive traces, e.g., 104a and 104j can be used for input/output functionality. Some conductive traces, e.g., 104b-c and 104h-l, can be used for connections to active/passive components such as IC die, etc. Some conductive traces, e.g., 104d-e and 104f-g, can be used for connections to fractional coil structures as part of transformer coils, as described in further detail below. Of course, additional conductive structures/traces can be present for substrate 101 in addition to those shown, e.g., in or on one or more portions of substrate 101 extending into and/or out of the drawing plane.

View B shows structure 100B including magnetic core 106, shown with representative cross sections 106a-b, added to structure 100A of View A. While cross sections 106a-b are shown as having certain shapes, those are merely provided for example; a person of ordinary skill in the art will understand that the magnetic core 106 may have any suitable cross section, e.g., circular, rectangular with rounded corners, etc. Core 106 can include soft ferromagnetic material, e.g., ferrite, a nickel alloy, or SiFe, and may have a closed shape, e.g., a toroidal or rectangular shape, as shown. In some embodiments, an insulator material can be provided to the magnetic core to provide isolation. In some embodiments, the core may be insulated with an insulating tape on the core side(s)/surface(s) facing an adjacent substrate.

View C shows an example fractional coil structure 108 (a.k.a., coil package or coil winding package) having one or more (e.g., a plurality of) fractional coil windings shown as 109a-b (e.g., as leads) that are held/pass through body 110. The fractional coil windings 109a-b may made be made of or include any suitable conductive material. Body 110 can be made of or include any suitable material, e.g., an insulative or dielectric molding material. For example, in some embodiments, tape can be used to hold leadframes together.

View D shows structure 100D including first and second fractional coil structures 108a-b and first and second integrated circuit (IC) die (a.k.a., semiconductor die) 112a-b added to structure B shown in View B. First and second fractional coil structures 108a-b are positioned adjacent respective cross sections 106a-b of core 106. The plurality of conductive structures (e.g., leads) of first and second fractional coil structures 108a-b form respective portions of the galvanically separated first (primary) and second (secondary) coils 111a-11b of transformer 120. The fractional coil structures 108a-b, including respective leads 109a′-b′ and 109a″-b,″ are preferably configured to avoid direct contact with core 106, as indicated. Fractional coil structures 108a-b may be formed/configured as packaged leads (lead packages) in some embodiments. IC die 112a-b are shown connected to respective portions of conductive traces 104 by solder balls 113.

Fractional coil structures 108a-b together with respective coil structures of the substrate 101, shown as 104e′ and 104f′, form separate first and second coils 111a-111b (e.g., primary and secondary coils) of transformer 120. Fractional coil structure 108a (e.g., with portions of multiple coil windings shown as leads 109a′-b′) together with portions of conductive traces, e.g., 104e′, form windings of first (primary) coil 111a. Fractional coil structure 108b (e.g., with portions of multiple coil windings shown as leads 109a″-b″) together with portions of conductive traces, e.g., 104f′, form windings of second (secondary) coil 111b. The first and second coils 111a, 111b (along with connected conductive structure) are galvanically separated on primary and secondary sides of transformer 120 and may each coil have a desired number of windings (coil loops) configured about core 106, which can be a different number for each coil.

View D also shows the addition of first and second semiconductor die (a.k.a., IC die) 112a, 112b, which may be connected to first and second coils 111a, 111b, respectively. In some examples and embodiments, IC 100 package may include a gate driver (e.g., as an IC in die 112b) that is galvanically isolated by the transformer structure 120. In some embodiments and examples, the secondary side of transformer 120 may be a high voltage side, e.g., with transformer 120 configured as a step up transformer. Other passive and/or active components (not shown) may also be provided for (e.g., place on) substrate 101 for IC package 100. In some embodiments, dielectric material(s), e.g., one or more coatings and/or tape, may be placed over the core 106 prior to mounting fractional coil structures 108a-b, which may be formed/configured as packaged leads. In some embodiments, a space or region (spacing) 115 between core 106 and first and second fractional coil structures 108a-b can be occupied by mold material, e.g., shown as 114 in view (E) used as insulator. In some embodiment, leads 109a′-b′ and/or leads 109a″-b″ may be covered with suitable insulative material(s), e.g., a dielectric gel, an insulator, and/or a parylene coating, after attachment to substrate 101.

View E shows structure 100E including structure 100D of View D covered by an optional encapsulant (encapsulate) material 114. Any suitable material may be used for encapsulant 114. In some embodiments, encapsulant 114 can include a silicone material. In some embodiments, encapsulant 114 can include a molding (mold) material. The encapsulated structure can form an IC package 130, in some embodiments. Other embodiments can utilize the structure shown with less encapsulant than as shown or with no encapsulant. As noted previously, in some embodiments, a region or space 115 between the core 106 and first and second fractional coil structures 108a-b can be occupied by mold material 114; in some embodiments, other materials may be used to fill space 115. For example, in some embodiments, space 115 may be occupied by a dielectric gel, or a silicone based underfill type of material may be utilized to fill the space 115 and be more flexible than, e.g., epoxy mold compound.

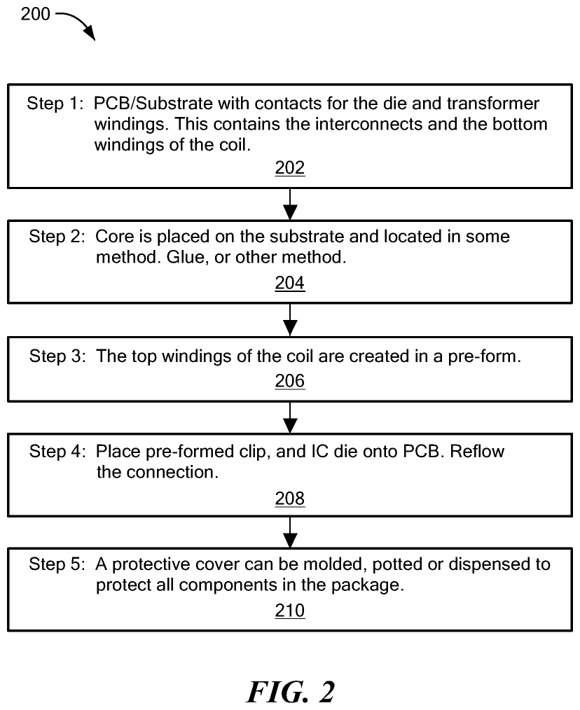

FIG. 2 is a diagram showing an example method 200 of fabricating a transformer-based integrated circuit (IC) package having fractional coil structures with steps corresponding to the structures shown in FIG. 1.

Method 200 can include providing a substrate (e.g., PCB) with conductive structure (e.g., contacts) for IC die and portions of transformer coil windings, as described at 202 (Step 1). A magnetic core can be provided to, e.g., placed or disposed on, the substrate, as described at 204 (Step 2). The magnetic core can include one or more soft (referring to magnetism property) ferromagnetic material(s). In some embodiments, glue or epoxy may be used for placement of the magnetic core. A fractional coil structure with portions of coil windings (e.g., supplementary to those described at 202), may be provided, e.g., by preforming and/or molding, as described at 206 (Step 3). In some embodiments, the fractional coil structure may be or include a preformed structure, e.g., clip. The fractional coil structure (e.g., a preformed clip, or premolded lead frame structure) may be placed on the substrate and configured about the magnetic core, as described at 208 (Step 4). In some embodiments, the fractional coil structure may be subject to a reflow step/process for connection to the substrate. One or more IC die and/or other active/passive components may also be added. Any suitable mounting/bonding technique can be used for adding/mounting one or more ICs and/or other components. For example, wirebonds, flip chip connections, or tape-automated bonding (TAB) can be used for ICs in some embodiments. An optional protective cover may be added (e.g., molded, potted, dispensed, etc.) to protect components, as described at 210 (optional Step 5).

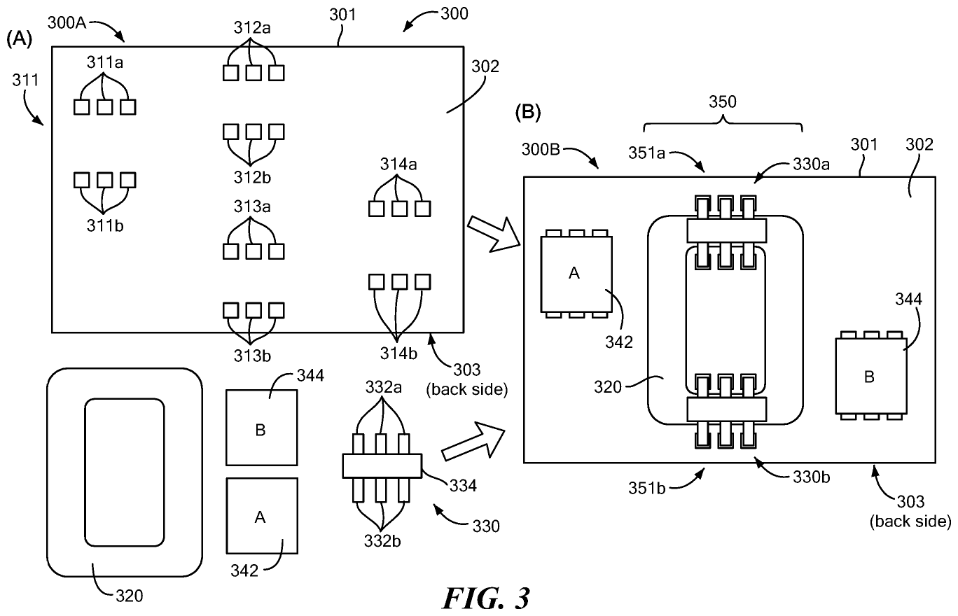

FIG. 3 is a diagram showing Views A-B of an example transformer-based integrated circuit (IC) package structure 300 having fractional coil structures in an unassembled state (300A) and an assembled state (300B), respectively, in accordance with the present disclosure.

As shown in View A, IC package structure 300A can include a substrate 301 having opposed first and second sides 302, 303. Substrate 301 can include conductive traces 311 including multiple pluralities of conductive traces, e.g., 311a-b, 312a-b, 313a-b, 314a-b, which can include (but are not required to have) suitable connections (not visible) within substate 301. Conductive traces 311 can be used for connections to and/or between active and/or passive components, as described in further detail below. A magnetic core 320 can be included. Magnetic core can include a soft ferromagnetic material. In some embodiment, e.g., for higher frequency operation, a laminated core 320 may be used. A laminated core may include metal or metallic material(s) in some embodiments. In some embodiments, a laminated core may include non-metallic materials, e.g., ferrite. For the configuration shown in views A and B, a laminated core 320 may have layers that are parallel to the plane of the figures. In other words, the magnetic flux paths would be broken in the vertical direction (perpendicular to the substrate), but not in the in-plane (in-substrate) direction. In some embodiment, the core layers may have a thickness (perpendicular to the plane of the substrate) in the range of about 50-250 microns; other thicknesses may be used in other embodiments. First and second IC die 340, 342, can be included as shown. First and/or second IC die 340, 342 may be in a die package in some embodiments (e.g., as shown) or may be exposed in other embodiments.

As shown in View A, package structure 300 can include one or more fractional coil structures 330. Each fractional coil structure 330 can include one or more (e.g., a plurality of) fractional coil windings shown as 332a-b that are held/pass through body 334. The fractional coil windings 332a-b may made be of or include any suitable conductive material. Body 334 can be made of or include any suitable material, e.g., an insulative or dielectric molding material (which may include an epoxy mold compound).

View B shows the components of package structure 300A of View A in an assembled state as an assembled package structure 300B. In some embodiments, a package may be formed with or based on package structure 300B, e.g., by applying a molding compound and application of a compression molding step. View B shows magnetic core 320 placed on substrate 301. Die (die packages) 342 and 344 are placed on substrate 301 and received by conductive structures 311a-b and 314a-b, respectively. Die 340 and 342 may be connected to conductive structures 311a-b and 314a-b by any suitable means, e.g., solder or the like. In some alternative embodiments, the die 342 and/or 344 may be mounted to the substrate 301 (e.g., PCB) in a flip-chip configuration using conductive balls or bumps, or in a chip on board configuration using wire bonds to connect the die 342 and/or 344 to the substrate 301. First and second fractional coil structures 330a-b are mounted to substrate 301 at conductive structures 312a-b and 313a-b, respectively. The fractional coil structures 330a-b and respective conductive structures 312a-b and 313a-b of substrate 301 are configured as first and second coils about 351a-b core 320 and operational as a transformer 350 (having primary and secondary sides) for IC package structure 300. Transformer 350 can provide galvanic isolation of/between IC die 342 and 344 and other portions of primary and secondary sides of transformer 350.

While two fractional coil structures 330a-b are shown for IC package structure 300, other embodiments can have fewer or more fractional coil structures. For example, in some embodiments, a single fractional coil structure con be used for one coil of transformer 350 while a different coil structure is used for another coil of the transformer. In other embodiments, more than two fractional coil structures can be used, e.g., embodiments having a single primary coil and two or more secondary coils.

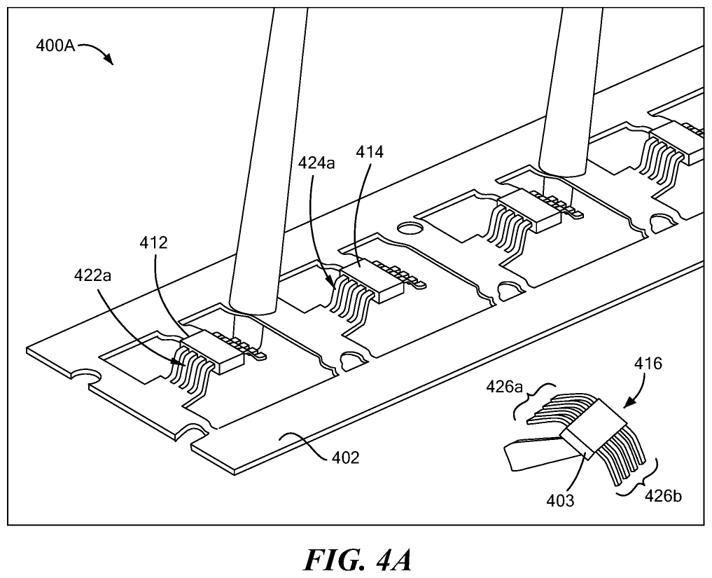

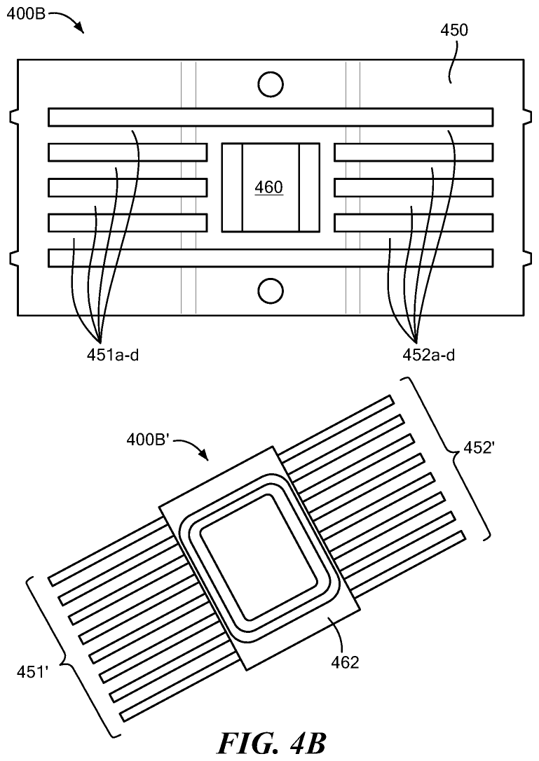

FIG. 4A is a diagram of an example of structure 400A for a contactor molding and leadforming process, in accordance with the present disclosure. Structure 400A includes an outer (main) leadframe 402 with cutouts forming multiple smaller leadframes 412, 414, 416, each having sets of leads (422a-b, 424a-b, 426a-b) that can be used for fractional coil structures in accordance with the present disclosure. Contactor molding 403 can be applied as shown for each fractional coil structure. The leadframes 412, 414, 416 can have bodies (not shown) molded to produce individual fractional coil structures having leads/conductive traces with desired pitch and alignment, in accordance with the present disclosure.

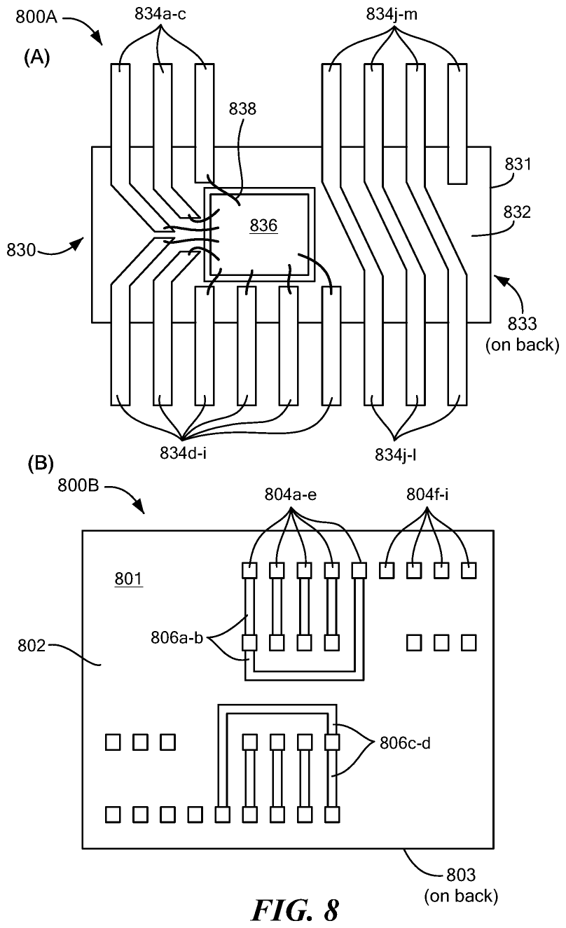

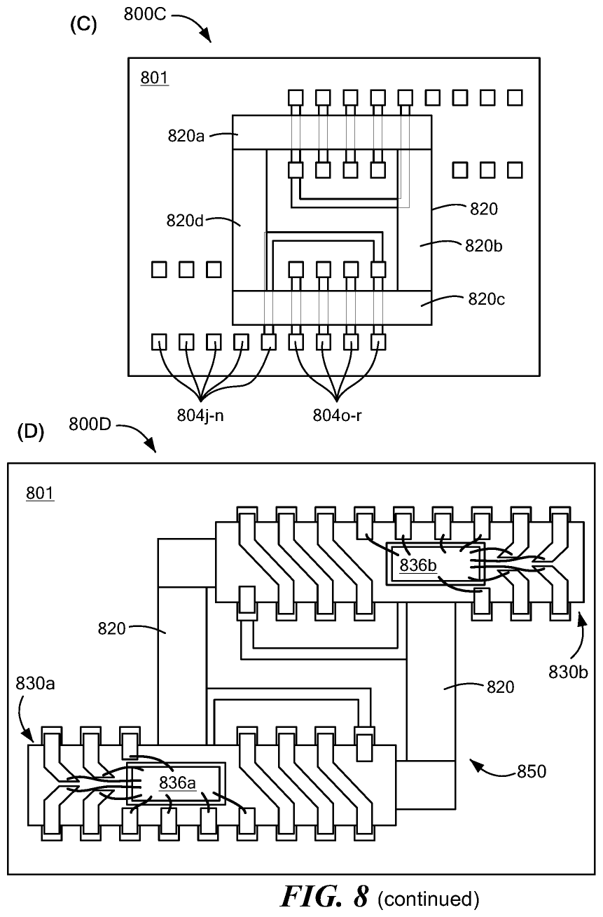

FIG. 4B is a diagram of an example long-lead dual in-line-package (DIP) 400B that can be used for a fractional coil structure in some embodiments. An outer leadframe 450 can have material selectively removed by a suitable technique (e.g., by etching, laser cutting, etc.) to form a plurality of leads (conductive traces) 451a-d and 452a-d. In some embodiments, an optional die pad 460 may be present for receiving a semiconductor die (a.k.a., integrated circuit die) with an integrated circuit (IC). In some embodiments leads 451a-d are connected to leads 452a-d, respectively. In some embodiments, other configurations of connections may exist between leads 451a-d and 452a-d (see, e.g., FIG. 8). Finished DIP 400B′ (at right) includes a package body (e.g., a molded body) 462, which may encapsulate one or more semiconductor die (not shown). Finished DIP 400B′ includes two sets of leads 451′, 452′ each having a desired number or leads and a desired pitch between the leads.

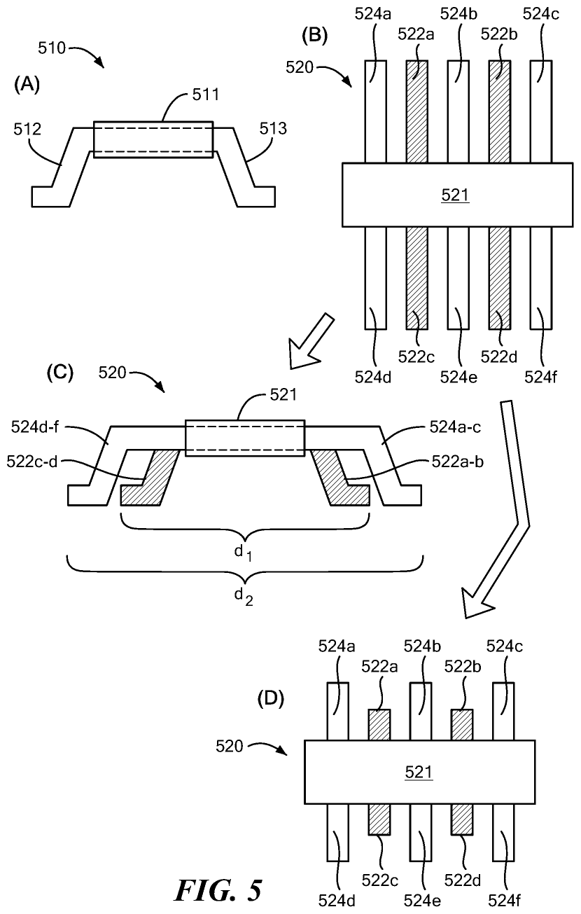

FIG. 5 is a diagram with Views A-D showing different lead configurations, in accordance with example embodiments of the present disclosure. View A shows fractional coil structure 510 with body 511 and lead sets 512, 513. As shown, the leads in lead sets 512 and 513 share a common configuration (bent shape).

Views B-D show an alternate embodiments of a fractional coil structure 520 with leads having different configurations. View B shows a top view fractional coil structure 520 having body 521 and lead sets 522a-b and 524a-c (at the top) and lead sets 522c-d and 524d-f (at the bottom), with the leads having straight configurations, prior to shaping for attachment.

View C shows a side view of fractional coil structure 520 with the lead sets configured for attachment, e.g., to a substrate. As shown, leads 522a-b have a different attachment location relative to body 521 compared to leads 524a-c; likewise, leads 522c-d have a different attachment location relative to body 521 compared to leads 524d-f. The difference in attachment locations is illustrated by comparing distance d₁ to distance d₂.

View D shows a top view of the fractional coil structure 520 shown in View C. As can be seen, the configuration of leads allows a higher density of leads (which can be used, e.g., as windings for a related transformer) for the given footprint of body 521.

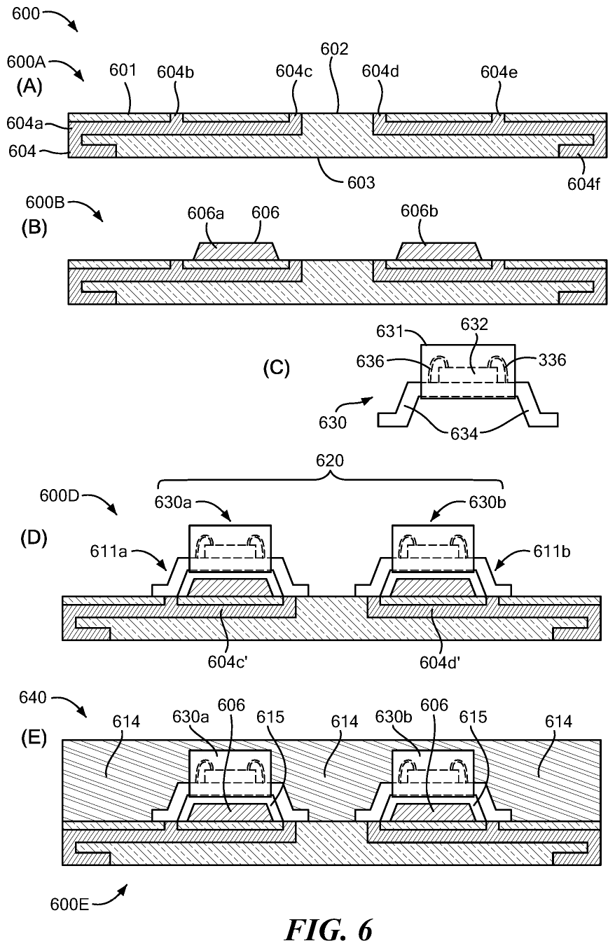

FIG. 6 is a diagram showing structure of a further example transformer-based integrated circuit (IC) package 600 having fractional coil structures with included IC die at successive stages of fabrication (shown in Views A-E), in accordance with the present disclosure.

As shown in View A, structure 600A includes substrate 601 includes opposed first and second sides (surfaces) 602, 603 and a plurality of conductive traces (conductive structures) 604. In the example shown, substrate 601 includes conductive traces 604, which include conductive trace 604a-604f. Some conductive traces, e.g., 604a and 604f, can be used for input/output functionality. Some conductive traces (not shown) can be used for connections to active/passive components. Some conductive traces, e.g., 604b-c and 604d-e, can be used for connections to fractional coil structures as part of transformer coils, as described in further detail below. Additional conductive structures can be present for substrate 601 in addition to those shown, e.g., in or on one or more portions of substrate 601 extending into and/or out of the plane of the figure.

View B shows structure 600B including magnetic core 606, shown with cross sections 606a-b, added to structure 600A of View A. Core 606 can include soft ferromagnetic material, e.g., ferrite, a nickel alloy, or SiFe, and may have a closed shape, e.g., a toroidal or rectangular shape, as shown. In some embodiments, an insulator material can be provided to the magnetic core 606 to provide isolation. In some embodiments, the core 606 may be insulated with an insulating tape on the core side(s)/surface(s) facing an adjacent substrate. IIn some embodiments, core 606 may be coated with one or more dielectric materials. As noted above, while core 606 is shown having a certain cross-sectional shape, core 606 may have any suitable cross-sectional shape, e.g., round, oval, rectangular, etc.

View C shows an example fractional coil structure 630 having an included IC die. Fractional coil structure 630 includes a body 631 and a plurality of conductive traces (leads) 634 that are held/pass through body 631. Body 631 can also include an IC die 632. Conductive traces 634 can include fractional coil windings (which can be used as part of a primary or secondary coil) as well as leads/traces for input/out functionality for IC die 632. IC die 632 may be connected to one or more of the conductive traces/leads 634 by suitable connections, e.g., wire bonds, etc. Conductive traces 634 may made be made of or include any suitable conductive material, e.g., copper, etc. Body 631 can be made of or include any suitable material, e.g., an insulative or dielectric molding material.

View D shows structure 600D with first and second fractional coil structures 630a-b (each similar to structure 630 of View C) added to structure 600B shown in View B. Fractional coil structures 630a-b together with respective coil structures of the substrate 601 form separate first and second coils 611a-611b (e.g., primary and secondary coils) of a transformer 620. Fractional coil structure 630a (e.g., with portions of multiple coil windings) together with portions of conductive traces 604, e.g., 604c′, form windings of a first coil 611a (e.g., a primary coil) of transformer 620. Fractional coil structure 630b (e.g., with portions of multiple coil windings) together with portions of conductive traces, e.g., 604d′, form windings of a second coil 611b (e.g., a secondary coil) of transformer 620. The first and second coils 611a, 611b may each have a desired number of windings (coil loops) configured about core 606, which can be a different number for each coil. In some examples and embodiments, structure 600D may include a gate driver (e.g., as an IC in die 632b) that is galvanically isolated from the IC die 632a by transformer structure 220. In some embodiments and examples, the secondary side of transformer 620 may be a high voltage side, e.g., with transformer 620 configured as a step up transformer.

View E shows structure 600E including the structure 600D of View D covered by an optional encapsulant (encapsulate) material 614. Any suitable material may be used for encapsulant 614. In some embodiments, encapsulant 614 can include a silicone material. In some embodiments, encapsulant 614 can include a molding material. The encapsulated structure can form an IC package 640, in some embodiments. Other embodiments can utilize the structure shown with less encapsulant than as shown or with no encapsulant. As noted previously for FIG. 1, in some embodiments, a region or space 615 between the core 606 and first and second fractional coil structures 630a-b can be occupied by mold material 614; in some embodiments, other materials may be used to fill space 615. For example, in some embodiments, space 615 may be occupied by a dielectric gel, or a silicone based underfill type of material may be utilized to fill the space 615 and be more flexible than, e.g., epoxy mold compound.

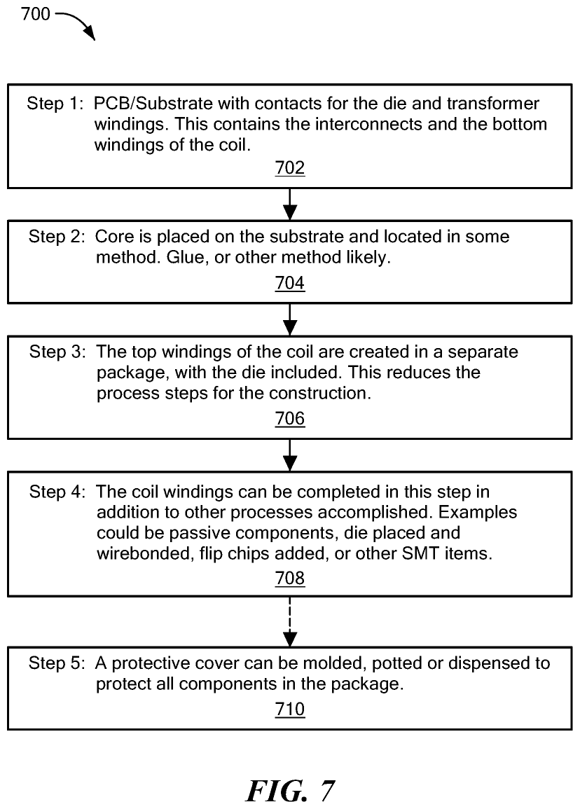

FIG. 7 is a diagram showing an example method 700 of fabricating a transformer-based integrated circuit (IC) package having fractional coil structures with steps corresponding to the structures shown in FIG. 6.

Method 700 can include providing a PCB/substrate with contacts for the die and portions (e.g., “lower winding” portions) of transformer windings, as shown at 702 (“Step 1”). The PCB/substrate can include the interconnects and portions (e.g., “bottom winding” portions) of the coils used for the transformer. A magnetic core can be placed on the substrate, as shown at 704 (“Step 2”). The magnetic core can include soft ferromagnetic material. Any suitable placement/location technique may be used. In some embodiments, a core may be affixed to or on the substrate by use of glue or epoxy. Other portions of the coils (e.g., “top winding” portions) can be formed in a separate package, as described at 706 (“Step 3”). In some embodiments, the separate package can include an IC die. The different winding portions can be joined, e.g., by placing the separate package(s) over the magnetic core, as described at 708 (“Step 4”). This can result in formation of complete first (primary) and second (secondary) coils of the transformer. Other active and passive components may be added during this step (or others). A protective later/cover can optionally be applied, as described at 710 (optional “Step 5”). In some embodiments, a protective cover/layer can be molded, potted, or dispensed.

FIG. 8 is a diagram showing Views A-D of an example transformer-based integrated circuit (IC) package 800 having fractional coil structures with included IC die, in accordance with the present disclosure.

View A shows a top section view of a fractional coil structure 800A including an IC die 836. Structure 800A includes a body (e.g., substrate or molded body) 830. Body 830 includes body material 831 with first side 832 and second side 833. Structure 800A includes a plurality of conductive traces 834a-m. In some embodiments, structure 800A also includes an IC die 836, which may be disposed on a die pad, e.g., shown as die pad connected to conductive trace 834g. As shown, some conductive traces 834a-i may be connected to IC die 836 by suitable connections, e.g., wire bonds 838. As shown, other conductive traces 834j-l are not connected to IC die 836. Some conductive traces can pass through body 830 without interruption, as shown by traces 834j-m, e.g., for use as one or more windings in a primary or secondary coil. Some conductive traces may originate/terminate at body 831, e.g., as indicated by conductive trace 834m. IC die 836 may include an integrated circuit, e.g., control circuity and/or a gate driver. In some embodiments, fractional coil structure 800A can include or be configured as a pre-formed clip.

View B shows structure 800B includes a substrate 801 (e.g., PCB) used for an example transformer-based integrated circuit (IC) package, in accordance with the present disclosure. Substrate 801 includes a first side 802 and a second side 803. Substrate 801 includes a plurality of conductive traces/structures including exposed pads 804 (e.g., including 804a-i) and buried traces 806 (e.g., including 806a-d). Substrate 801 and the included conductive traces/structures are configured to receive a magnetic core and a plurality (e.g., two) of fractional coil structures (such as 800A shown in View A) that can form complete transformer coils when connected to conductive structures (e.g., certain of pads 804 and buried traces 806) of substrate 801.

View C shows structure 800C, which includes structure 800B of View B with the addition of magnetic core 820. Magnetic core 820 can include one or more soft ferromagnetic materials. In some embodiments, magnetic core 820 may have a plurality of pieces/sections, which can be affixed or connected to one another (e.g., positioned next to and in contact) to facilitate flow of magnetic flux. For example, core 820 is shown with four component pieces 820a-d. Structure 800C is configured to receive/support a plurality of fractional coil structures 800A shown in View A, e.g., by connections at pads 804j-r.

View D shows structure 800D which includes structure 800C of View C along with two fractional coil structures 830a and 830b (each similar to structure 800A shown in View A) mounted to substrate 801. Structure 800D can include suitable conductive structure for input/output functionality, e.g., conductive pads on the second side 803 (not shown) of substrate 801. Conductive traces in substrate 801 are in contact with coil portions in fractional coil structures 830a and together can form a first (primary) coil about core 820. Conductive traces in substrate 801 are in contact with coil portions in fractional coil structure 830b and together can form a second (secondary) coil about core 820. The first and second coils and core 820 can be configured as a transformer 850 as shown. Each of fractional coil structures 830a and 830b can include a desired IC die 836a, 836b, which can be galvanically isolated from one another by the transformer 850. In some embodiments, an IC in an IC die 836b on the secondary side of transformer 850 can include a gate driver, e.g., configured to drive a solid state power switch such as a FET (e.g., SiC FET or GaN FET) or IGBT, or some other load. In some embodiments, an optional protective layer, e.g., encapsulant, potting material, and/or molding material may be applied to structure 800D to form an IC package.

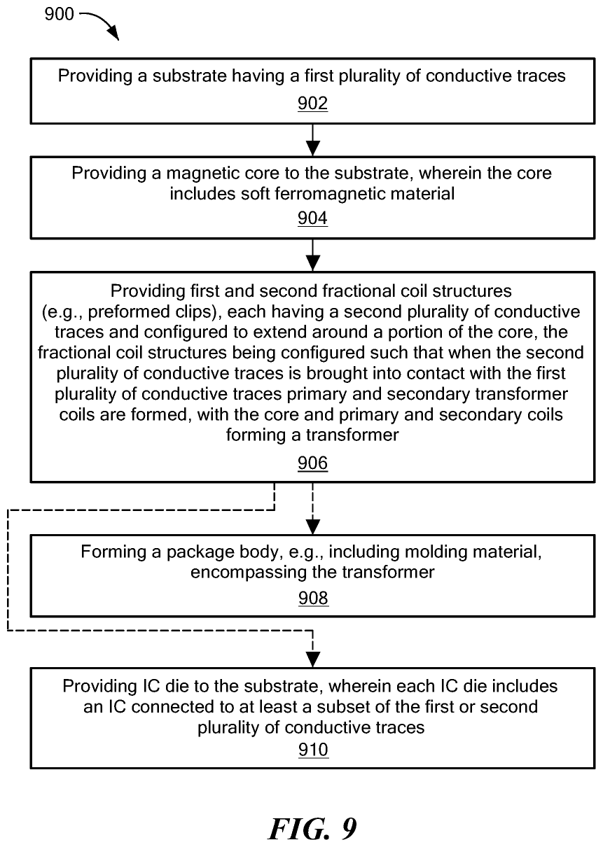

FIG. 9 is a diagram showing an example method 900 of fabricating a transformer-based integrated circuit (IC) package having fractional coil structures, in accordance with the present disclosure.

Method 900 can include providing a substrate having a first plurality of conductive traces, as described at 902. In some embodiments, the substrate may be or include a PCB. A magnetic core can be provided to the substrate, as described at 904. First and second fractional coil structures (e.g., preformed clips) can be provided, each having a second plurality of conductive traces and configured to extend around a portion of the core, as described at 906. In some embodiments, a single fractional transformer coil structure in accordance with the present disclosure may be used for one coil while a different coil construction may be used for another transformer coil. The fractional coil structures can be configured such that when the second plurality of conductive traces is brought into contact with the first plurality of conductive traces (of the substrate) first (primary) and second (secondary) transformer coils are formed, with the core and primary and secondary coils forming a transformer.

A package body can be formed as an optional step, as described at 908. The package body may encapsulate or cover the core and fractional coil structures of the transformer. In some embodiments, one or more IC die (packaged or unpackaged) can be provided to the substrate, as described at 910. For example, in some embodiments first and second IC die can be provided to the substrate prior to the optional encapsulation step. In some embodiments, one or more IC die (packaged or unpackaged) can be provided to one or more fractional coil structure. In some embodiments, the transformer may be configured as a step up transformer. In some embodiment, the second IC die can include a gate driver.

In some examples and/or embodiments, integrated circuits (ICs), e.g., in IC die 342 and 344 in FIG. 3 (View B), or other conductive features of the primary and secondary sides of a transformer structure in an IC or transformer package according to the present disclosure can be fabricated or configured to have a desired separation distance (d) between certain parts or features, e.g., to meet internal creepage or external clearance requirements for a given pollution degree rating as defined by certain safety standards bodies such as the Underwriters Laboratories (UL) and the International Electrotechnical Commission (IEC). For example, a separation distance may be between closest (voltage) points of the respective circuits, e.g., the low-voltage (primary) side and high-voltage (secondary) side. For further example, such a separation distance may be the distance between any two voltage points between the primary and secondary sides, e.g., distance between die 342 and die 344 in FIG. 3 (View B), or a distance between exposed leads connected to the die, may be or may be at least 1.2 mm, 1.4 mm, 1.5 mm, 3.0 mm, 4.0 mm, 5.5 mm, 7.2 mm, 8.0 mm, 10 mm, or 10+mm in respective examples. Such a distance between conductive portions or areas of die can include any insulation covering a conductor, e.g., such as plastic coating of a wire/lead. Other distances between conductive parts, components, and/or features of an IC/transformer package may also be designed and implemented, e.g., to meet desired internal creepage, voltage breakdown, or external clearance requirements, e.g., between external leads.

In some examples and embodiments, a dielectric material (e.g., gel) may be used for potting and/or protecting substrate (e.g., PCB) systems, assemblies, and/or packages, to protect die and/or interconnects from environment conditions and/or to provide dielectric insulation. In some examples, a dielectric material may include, but is not limited to, one or more of the following materials: DOWSIL™ EG-3810 Dielectric Gel (made available by The Dow Chemical Corporation, a.k.a., “Dow”, and DOWSIL™ EG-3896 Dielectric Gel (made available by Dow), which has the ability to provide isolation greater than 20 kV/mm. Other suitable gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications.

Accordingly, embodiments and/or examples of the inventive subject matter can afford various benefits relative to prior art techniques. For example, embodiments and examples of the present disclosure can enable or facilitate use of smaller size packages for a given power, current. or voltage rating. Embodiments and examples of the present disclosure can enable or facilitate lower costs and higher scalability for manufacturing of IC packages/modules having voltage-isolated (galvanic isolation) IC die and transformers.

Various embodiments of the concepts, systems, devices, structures, and techniques sought to be protected are described above with reference to the related drawings. Alternative embodiments can be devised without departing from the scope of the concepts, systems, devices, structures, and techniques described. For example, in some embodiments, fractional coil structures (e.g., primary and secondary transformer coils) may have a whole number or fractional number of turns (loops about a related core), e.g., 1.5, 2.5, 1.75, 1.8, 2.25, 6.5, 8.8, etc.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more” and “at least one” indicate any integer number greater than or equal to one, i.e., one, two, three, four, etc. The term “plurality” indicates any integer number greater than one. Those terms, however, may refer to fractional numbers/values where context admits, e.g., a number of loops in a transformer coil may be a plurality that includes a fractional value, e.g., 2.75, 3.5, 4.25, etc. The term “connection” can include an indirect connection and a direct connection.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A transformer-based integrated circuit (IC) package comprising:
a substrate having a first plurality of conductive traces;
a core disposed on the substrate, wherein the core includes a soft ferromagnetic material; and
a pair of fractional coil structures, each having a second plurality of conductive traces and configured to extend around a portion of the core, wherein the pair of fractional coil structures is configured such that primary and secondary coils are formed when the second plurality of conductive traces is brought into contact with the first plurality of conductive traces;
wherein the primary and secondary coils are configured with the core as a transformer.

2. The IC package of claim 1, further comprising at least one semiconductor die disposed on the substrate.

3. The IC package of claim 2, wherein the at least one semiconductor die comprises an integrated circuit (IC).

4. The IC package of claim 3, wherein the IC is connected to the secondary coil.

5. The IC package of claim 4, wherein the transformer is configured as a step-up transformer.

6. The IC package of claim 5, wherein the IC comprises a gate driver.

7. The IC package of claim 1, wherein the substrate comprises a printed circuit board (PCB).

8. The IC package of claim 7, wherein the PCB comprises FR4.

9. The IC package of claim 1, wherein the core comprises ferrite.

10. The IC package of claim 1, wherein the core comprises iron powder.

11. The IC package of claim 1, wherein the core comprised a laminated metal core.

12. The IC package of claim 1, wherein at least one fractional coil structure comprises a semiconductor die disposed on a substrate, wherein the semiconductor die includes an integrated circuit (IC).

13. The IC package of claim 12, wherein the IC is connected to a subset of the second plurality of conductive traces.

14. The IC package of claim 13, wherein the IC comprises a gate driver, and wherein the second plurality of conductive traces is connected to the secondary coil.

15. The IC package of claim 1, wherein at least one fractional coil structure comprises a leadframe.

16. The IC package of claim 1, wherein the core comprises a plurality of core portions.

17. The IC package of claim 16, wherein the plurality of core portions are connected at joints including ferrite-loaded epoxy.

18. The IC package of claim 1, further comprising a package body including the substrate.

19. The IC package of claim 18, wherein the package body includes a molding material.

20. The IC package of claim 18, wherein the package body includes a potting material.

21. A method of making a transformer-based integrated circuit (IC) package, the method comprising:
providing a substrate having a first plurality of conductive traces;
providing a core disposed on the substrate, wherein the core includes a soft ferromagnetic material; and
providing a pair of fractional coil structures, each having a second plurality of conductive traces and configured to extend around a portion of the core, wherein the pair of fractional-coil structure is configured such that primary and secondary coils are formed when the second plurality of conductive traces is brought into contact with the first plurality of conductive traces;
wherein the primary and secondary coils are configured with the core as a transformer.

22. The method of claim 21, further comprising providing at least one semiconductor die disposed on the substrate, wherein the at least one semiconductor die comprises an integrated circuit (IC).

23. The method of claim 22, wherein the IC is connected to the secondary coil.

24. The method of claim 23, wherein the transformer is configured as a step-up transformer.

25. The method of claim 24, wherein the IC comprises a gate driver.

26. The method of claim 21, wherein the substrate comprises a printed circuit board (PCB).

27. The method of claim 26, wherein the PCB comprises FR4.

28. The method of claim 21, wherein the core comprises ferrite.

29. The method of claim 21, wherein the core comprises iron powder.

30. The method of claim 21, wherein the core comprised a laminated metal core.

31. The method of claim 21, wherein at least one of the pair of fractional coil structures comprises an IC die disposed on a substrate, wherein the IC die comprises an IC.

32. The method of claim 31, wherein the IC is connected to a subset of the second plurality of conductive traces.

33. The method of claim 32, wherein the IC comprises a gate driver, and wherein the second plurality of conductive traces is connected to the secondary coil.

34. The method of claim 21, wherein at least one fractional coil structures comprises a leadframe.
